(19) United States
(12) Patent Application Publication
(10) Pub. No.: US 2016/0291104 A1
(43) Pub. Date: Oct. 6, 2016

(54) MAGNETIC RESONANCE IMAGING APPARATUS

(71) Applicant: HITACHI, LTD., Chiyoda-ku, Tokyo (JP)

(72) Inventor: Munetaka TSUDA, Tokyo (JP)

(21) Appl. No.: 15/035,535

(22) PCT Filed: Nov. 13, 2014
(86) PCT No.: PCT/JP2014/080021

§ 371 Date: May 10, 2016

(30) Foreign Application Priority Data
Nov. 29, 2013 (JP) 2013-247995

(51) Int. Cl. G01R 33/3815; H01F 6/04; H01F 6/06; G01R 33/38

(52) U.S. Cl. CPC G01R 33/3815; G01R 33/3804; G01R 33/3806; H01F 6/04; H01F 6/06

(57) ABSTRACT

An MRI apparatus is provided in which, in a superconducting magnet using a high-temperature superconducting wire, deterioration in a heat insulation function of a vacuum tank can be prevented even in a case where cooling performed by a freezer is stopped for a long period of time, and thus rapid cooling can be performed so that a temperature is reduced to a threshold temperature or lower of the high-temperature superconducting wire after an operation of the freezer is resumed. For this, the MRI apparatus includes a superconducting coil 105 that generates a static magnetic field, a vacuum container 107 that accommodates the superconducting coil 105, a freezer that is in thermal contact with the superconducting coil 105 so as to cool the superconducting coil 105, and a vacuum degree reduction preventing portion (205 and the like) which prevents a degree of vacuum of the vacuum container from being reduced in a case where a cooling function of the freezer is deteriorated or stopped.

### TECHNICAL FIELD

The present invention relates to a magnetic resonance imaging apparatus (hereinafter, referred to as an MRI apparatus) using a superconducting magnet, and particularly to an MRI apparatus using a superconducting magnet which maintains a superconducting coil at a threshold temperature or lower through conduction cooling by using a freezer.

### BACKGROUND ART

An MRI apparatus using a superconducting magnet has an advanced diagnosis function due to a strong and highly uniform magnetic field. Therefore, the apparatus is frequently provided for clinical examination in medical institutions.

The superconducting magnet is required to maintain a constituent superconducting coil to be cooled at a threshold temperature or lower.

In a lot of superconducting coils, a superconducting wire made of an alloy of NbTi is fixed in a solenoid form, and is cooled to a very low temperature of about 4 Kelvin (−269° C.) with liquid helium, so that a superconducting state is achieved. For this reason, the superconducting magnet employs a cryostat having a liquid helium container covered with a vacuum heat insulating tank in order to stably maintain the very low temperature. Generally, the cryostat has a radiation heat shield structure or is constituted of a freezer which recondenses a vaporized helium gas in order to reduce consumption of liquid helium.

A superconducting magnet including a radiation heat shield tank storing liquid nitrogen is also known (PTL 1). The liquid nitrogen is stored in the radiation heat shield tank, and cools the radiation heat shield tank so that the temperature thereof is maintained at the boiling point of 77 Kelvin of nitrogen. The cooled radiation heat shield tank reduces heat radiated to a helium container into which a superconducting coil is incorporated. In a case where an operation of the freezer is stopped due to power failure or system failure, the liquid helium or the liquid nitrogen functions as a cold storage agent, and thus the superconducting coil is stably maintained at 4 Kelvin which is the boiling point of liquid helium.

On the other hand, in order to generate magnetic field strength higher than magnetic field strength obtained by NbTi of the related art, and to achieve a superconducting state without using a liquid helium refrigerant, a superconducting magnet using a high-temperature superconducting wire is also known. The high-temperature superconducting wire is brought into a superconducting state at about 20 Kelvin to 70 Kelvin, and thus a structure is employed in which a superconducting coil is disposed inside a vacuum heat insulating tank, conduction cooling is continuously performed by using a freezer, and an operation is performed while maintaining a low temperature at which superconduction occurs.

The cooling using the freezer has no heat storage effect as in a refrigerant, and the low temperature at which superconduction occurs cannot be maintained only with the vacuum heat insulating tank. Thus, when an operation of the freezer is stopped, the temperature of the superconducting coil simultaneously increases. For this reason, energy accumulated in the superconducting coil is consumed by an external element, and thus the temperature of the superconducting coil does not increase to a high temperature. Consequently, when the function of the freezer is recovered again, the superconducting magnet can be brought into a magnetized state without requiring time for cooling the superconducting coil.

However, the superconducting magnet with the structure in which an operation is performed while conduction cooling of the high-temperature superconducting wire is performed by the freezer can be returned to a magnetized state within a short period of time when an operation of the freezer is resumed in a case where an operation of the freezer is stopped for a short period of time. However, in a case where an operation of the freezer is stopped for a long period of time, the temperature of the superconducting coil cannot be decreased to a predetermined low temperature at which a superconducting state occurs even if the operation of the freezer is resumed. For example, if radiation heat or conduction heat exceeding heat capacity of the superconducting coil or a structural body of a radiation heat shield is continuously applied thereto, and thus the temperature of the superconducting coil or the radiation heat shield increases to 77 Kelvin which is the boiling point of nitrogen or higher, air (nitrogen and oxygen) molecules fixed as a solid hitherto start to float as a gas in the vacuum heat insulating tank accommodating the superconducting coil, and thus a degree of vacuum is deteriorated.

If the degree of vacuum of the vacuum heat insulating tank is once deteriorated, the air molecules work as heat conduction media, and thus heat conductivity considerably increases. Even if an operation of the freezer is resumed in this state, an amount of heat coming from the outside is large, and exceeds the cooling performance of the freezer. Therefore, the superconducting coil cannot be cooled to a target threshold temperature. In addition, the degree of vacuum before being deteriorated can be returned only in a case where the vacuum tank whose degree of vacuum is deteriorated once is connected to a high performance vacuum pump by a technical personnel, and the air is exhausted therefrom for a couple of days. During that time, the MRI apparatus cannot be used.

Therefore, a method has been proposed in which a refrigerant (nitrogen) of which specific heat is high and density is low in a cryogenic region which is equal to or less than 60 Kelvin is held in a solid state in a vacuum tank so as to be used as a cold storage material, and a temperature increase of the superconducting coil during power failure is suppressed by using heat capacity thereof (PTL 2).

### CITATION LIST

### Patent Literature

PTL 1: JP-A-63-51849

PTL 2: JP-A-2011-82229

### SUMMARY OF INVENTION

### Technical Problem

However, in the configuration disclosed in PTL 2, it may be considered that a cold storage effect of the cold storage material is not sufficiently effectively utilized, and, even if an operation of the freezer is stopped for a long period of time, the capability to prevent deterioration in a heat insulation function of the vacuum tank by suppressing a temperature increase of the superconducting coil or the radiation heat shield is not sufficient.

Therefore, the present invention has been made in consideration of the circumstances, and an object thereof is to provide an MRI apparatus in which, in a superconducting magnet using a high-temperature superconducting wire, deterioration in a heat insulation function of a vacuum tank can be prevented even in a case where cooling performed by a freezer is stopped for a long period of time due to power failure or system failure, and thus rapid cooling can be performed so that a temperature is reduced to a threshold temperature or lower of the high-temperature superconducting wire after an operation of the freezer is resumed.

### Solution to Problem

In order to achieve the above-described object, according to the present invention, there is provided a magnetic resonance imaging apparatus including a superconducting coil that generates a static magnetic field; a vacuum container that accommodates the superconducting coil therein; a freezer that is in thermal contact with the superconducting coil so as to cool the superconducting coil; and a refrigerant container that accommodates a refrigerant for cooling the superconducting coil in a case where a cooling function of the freezer is deteriorated or stopped, in which the refrigerant container is also used as a coil bobbin on which the superconducting coil is wound.

Alternatively, according to the present invention, there is provided a magnetic resonance imaging apparatus including a superconducting coil that generates a static magnetic field; a vacuum container that accommodates the superconducting coil therein; a freezer that is in thermal contact with the superconducting coil so as to cool the superconducting coil; a coil bobbin that is disposed inside the vacuum container and on which the superconducting coil is wound, and arrangement that is in contact with the coil bobbin; a refrigerant container that is disposed outside the vacuum container, and accommodates a refrigerant for cooling the superconducting coil; and a conduit that is connected to the refrigerant container and through which the refrigerant flows.

### Advantageous Effects of Invention

According to the present invention, in the superconducting magnet using the high-temperature superconducting wire, deterioration in a heat insulation function of the vacuum tank can be prevented even in a case where cooling performed by a freezer is stopped for a long period of time due to power failure or system failure. Therefore, rapid cooling can be performed so that a temperature is reduced to a threshold temperature or lower of the high-temperature superconducting wire after an operation of the freezer is resumed.

### BRIEF DESCRIPTION OF DRAWINGS

FIG. 1 is a sectional view illustrating an internal structure of a vacuum container constituting a superconducting magnet of an MRI apparatus according to the present invention.

FIG. 2 is a block diagram illustrating the entire configuration of the MRI apparatus of Embodiment 1.

FIG. 3 is a sectional view of the superconducting magnet constituting the MRI apparatus of Embodiment 1.

FIG. 4 is a graph illustrating temperature changes of a high-temperature superconducting coil and a radiation shield plate.

FIG. 5 is a flowchart illustrating an operation of the MRI apparatus of Embodiment 1.

FIG. 6 is a block diagram illustrating the entire configuration of an MRI apparatus of Embodiment 2.

FIG. 7 is a sectional view illustrating an internal structure of a vacuum container of a superconducting magnet illustrated in FIG. 6.

### DESCRIPTION OF EMBODIMENTS

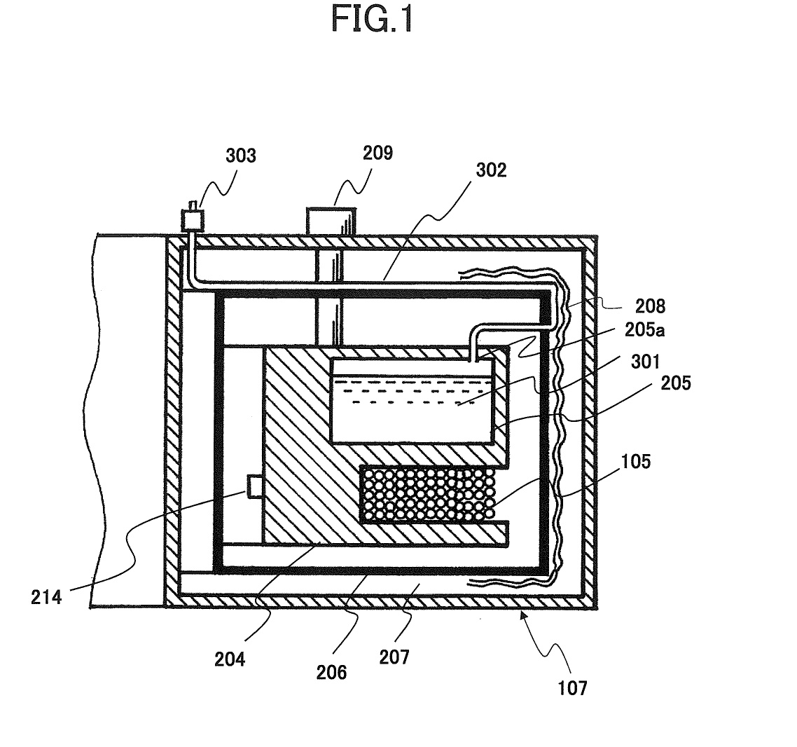

In the present invention, as illustrated in FIG. 1, there is provided an MRI apparatus including a superconducting coil 105 which generates a static magnetic field; a vacuum container 107 which accommodates the superconducting coil 105; a freezer which is in thermal contact with the superconducting coil 105 so as to cool the superconducting coil 105; and a vacuum degree reduction preventing portion (205 and the like) which prevents a degree of vacuum of the vacuum container from being reduced in a case where a cooling function of the freezer is deteriorated or stopped.

Hereinafter, embodiments of the present invention will be described with reference to the accompanying drawings. In addition, constituent elements having the same function are given the same reference numeral throughout all the drawings for explaining the embodiments of the present invention, and description thereof will not be repeated.

### Embodiment 1

In Embodiment 1, as the vacuum degree reduction preventing portion, a refrigerant container 205 which accumulates a refrigerant for cooling the superconducting coil 105 is provided. As the refrigerant, a refrigerant (for example, nitrogen) is used, which is solidified at a temperature to which the freezer cools the superconducting coil 105. The refrigerant container 205 is disposed inside the vacuum container 107. The refrigerant container 205 is also used as a coil bobbin 204 on which the superconducting coil 105 is wound. The refrigerant container 205 is connected to a refrigerant conduit 302 for making a refrigerant flow, and an end part of the refrigerant conduit 302 is drawn out of the vacuum container 107, and thus a gasified refrigerant is discharged to the outside. A check valve 303 is provided at the end part of the refrigerant conduit 302.

A radiation heat shield plate 206 is disposed inside the vacuum container 107 so as to cover the superconducting coil 105, and the refrigerant conduit 302 is disposed to be in contact with the radiation heat shield plate 206. Preferably, at least a partial interval of the refrigerant conduit 302 is disposed to be in thermal contact with and along the radiation heat shield plate 206.

Hereinafter, the MRI apparatus of Embodiment 1 will be described in more detail.

### Entire Configuration of MRI Apparatus of Embodiment 1

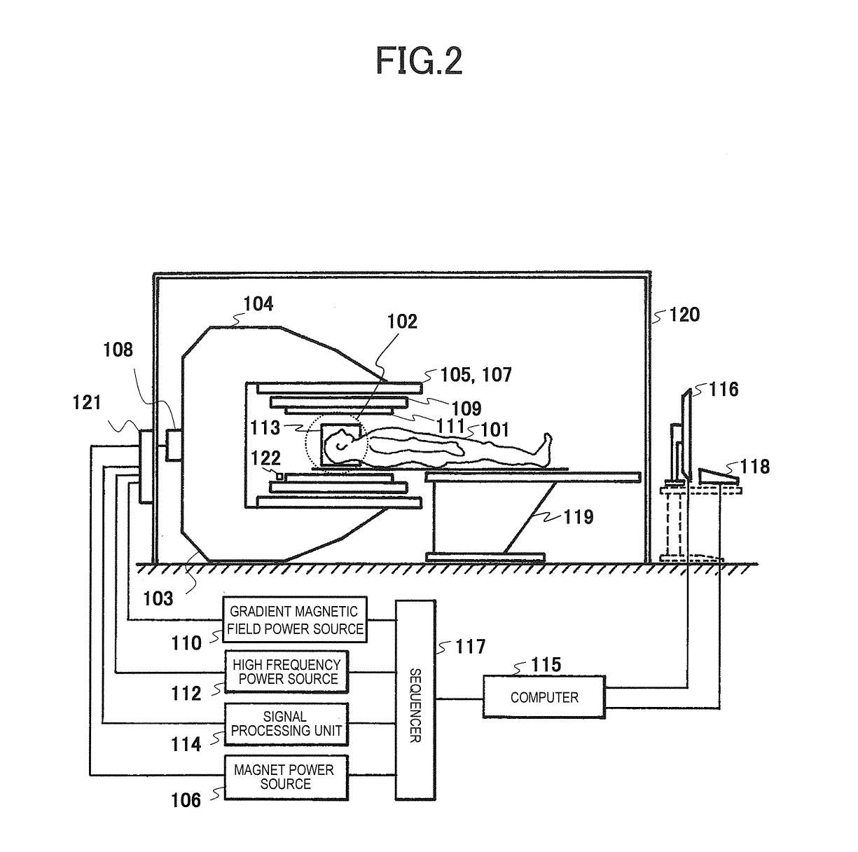

FIG. 2 illustrates a state in which the MRI apparatus of Embodiment 1 is provided in a medical institution and captures a medical diagnosis image of a patient who is an object.

An examination part of an object 101 is disposed at the center of an imaging space 102 in which a uniform static magnetic field is generated. A superconducting magnet 103 which generates the uniform static magnetic field in the imaging space 102 is configured to include an iron yoke 104 having two magnetic poles serving as NS poles, a pair of high-temperature superconducting coils 105, and a magnet power source 106. The iron yoke 104 constitutes a magnetic circuit, and also has a function of supporting the vacuum container 107 in which the pair of high-temperature superconducting coils 105 is disposed. With this configuration, a visual field is not blocked on the front side (y axis) and both of left and right sides (x axis) of the imaging space 102, and thus an open examination environment can be provided. The magnetic circuit constituted of the iron yoke 104 minimizes a leakage magnetic field spreading to the outside of the superconducting magnet 103.

The high-temperature superconducting coil 105 is stored in the vacuum container 107, and is cooled to 20 Kelvin which is equal to or less than a threshold temperature by a freezer 108 and is thus maintained in a stable superconducting state. A current of 160 amperes is applied from the magnet power source 106, and thus magnetic flux with a strength of 0.5 teslas is generated along the z axis in the imaging space 102 (the z axis is commonly used as a direction of magnetic flux in the academic field).

Gradient magnetic field coil assemblies 109 are attached to the two magnetic poles of the iron yoke 104, and generate gradient magnetic fields in which magnetic flux density has a gradient in three-axis directions orthogonal to each other in the imaging space 102. Although not differentiated in FIG. 2, three types of coils of x, y, and z are laminated in the gradient magnetic field coil assembly 109. For example, if a positive current flows through the z gradient magnetic field coils, the z gradient magnetic field coil attached to the upper magnetic pole generates magnetic flux in the same+z axis direction as that of magnetic flux generated by the high-temperature superconducting coil 105, and the magnetic flux is superimposed on the magnetic flux generated by the high-temperature superconducting coil 105 so that magnetic flux density increases. On the other hand, the z gradient magnetic field coil attached to the lower magnetic pole generates magnetic flux along the −z axis in an opposite direction to that of the magnetic flux generated by the superconducting coil 105 so that magnetic flux density decreases.

As a result, it is possible to generate a gradient magnetic field in which the magnetic flux density increases upward from the bottom along the z axis of the imaging space 102. The x gradient magnetic field coils change the density of magnetic flux generated by the superconducting coil 105 along the x axis of the imaging space 102, and the y gradient magnetic field coils change the density of magnetic flux generated thereby along the y axis of the imaging space 102. Gradient magnetic field power sources 110 which operate separately from each other are connected to the x, y and z gradient magnetic field coils, and each thereof causes a current of 500 amperes to flow so as to generate a gradient magnetic field of 25 mT/m whose magnetic field strength of 25 milliteslas per meter changes.

A pair of high frequency transmitter coils 111 is incorporated into the gradient magnetic field coil assembly 109 on the imaging space 102 side. The high frequency transmitter coils 111 are configured to have a plate structure so as not to hinder an open examination environment, and coil conductors are printed so that magnetic flux which is parallel to the x-y plane of the imaging space 102 is generated. A plurality of capacitive elements are incorporated (not illustrated in FIG. 2) into the high frequency transmitter coil so as to form an LC resonance circuit of 21 MHz. A high frequency current of 21 MHz flows through the high frequency transmitter coils 111 from a high frequency power source 112, and thus a high frequency magnetic field is generated in the imaging space 102.

A combination of the above-described static magnetic field, gradient magnetic field, and high frequency magnetic field cause excitation of a nuclear magnetic resonance (hereinafter, referred to as NMR) phenomenon in a hydrogen nuclear spin of an examination part of the object 101, and position information of x, y, and z is added to the Larmor precession of the hydrogen nuclear spin in the subsequent relaxation process.

In order to detect the Larmor precession of the hydrogen nuclear spin added with the position information in the above-described manner as an electric signal of NMR, a high frequency receiver coil 113 is attached to the examination part of the object 101. In the same manner as in the high frequency transmitter coil 111, a plurality of capacitive elements (not illustrated in FIG. 2) are incorporated into the high frequency receiver coil 113 so as to form a resonance circuit of 21 MHz. A difference from the high frequency transmitter coil 111 is that the high frequency receiver coil is fitted to a body's shape of the examination part so as to detect the Larmor precession of the hydrogen nuclear spin as an electric signal with high efficiency through electromagnetic induction. FIG. 2 illustrates a coil for detecting the head of the object 101.

An NMR signal detected by the high frequency receiver coil 113 is input to a signal processing unit 114 constituted of an amplifier and the like. The NMR signal undergoes an amplification process, a detection process, and an analog/digital conversion process in the signal processing unit 114 so as to be suitable for a calculation process performed by a computer 115.

The computer 115 performs a calculation process such as Fourier transform on the NMR signal which is then converted into a tomographic image or a spectral distribution chart which is effective for medical diagnosis. Such data is preserved in a storage device (not illustrated in FIG. 2) of the computer 115 and is also displayed on a display 116.

On the other hand, the computer 115 is connected to the respective units via an interface circuit referred to as a sequencer 117 so as to control the gradient magnetic field power source 110 and the high frequency power source 112 to be operated according to a timing chart called a pulse sequence. Thus, the computer obtains a target NMR signal from the examination part of the object 101. An input device 118 on which an operator of the MRI apparatus selects a pulse sequence is connected to the computer 115.

A patient table 119 for carrying the examination part of the object 101 into and out of the center of the imaging space 102 is provided on the front side of the superconducting magnet 103. The superconducting magnet 103 and the patient table 119 are provided in an examination room 120 which is shielded from electromagnetic waves. The units inside and outside the examination room 120 are connected to each other via a filter circuit 121. The filter circuit has a function of preventing electromagnetic waves emitted from the computer 115 or other power source units from entering the high frequency receiver coil 113 as noise.

<Structure of Superconducting Magnet>

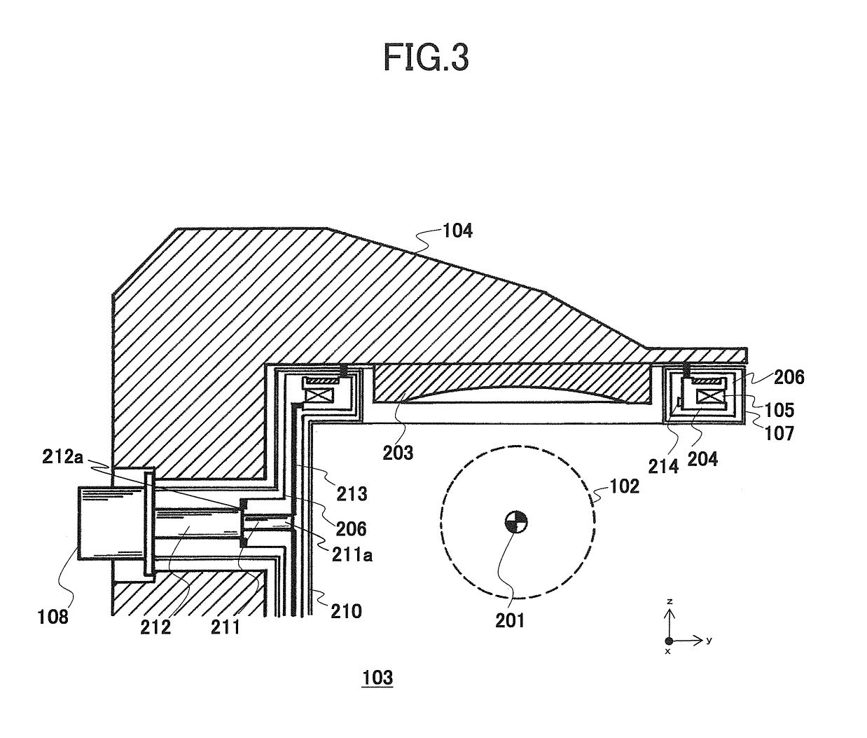

FIGS. 1 and 3 are sectional views for explaining a structure and a function of the superconducting magnet 103 described in FIG. 2. The superconducting magnet 103 has a structure in which a pair of vacuum containers 107 are disposed to oppose each other with the magnetic field center 201, and has a vertically symmetrical structure with respect to the x-y plane including the magnetic field center 201 except for the coil bobbin structure. Therefore, FIG. 3 illustrates an upper half part and does not illustrate a lower part. FIG. 1 is a sectional view illustrating details of internal structures of the upper and lower coil bobbins and the vacuum container 107. There may be a superconducting magnet having a structure in which a pair of vacuum containers 107 are disposed to be horizontally symmetrical with respect to the y-z plane including the magnetic field center 201.

The superconducting magnet 103 is constituted of the iron yoke 104, the vacuum container 107 storing the high-temperature superconducting coil 105 therein, and the freezer 108 which maintains the temperature of the high-temperature superconducting coil 105 to be equal to or lower than a threshold temperature.

The iron yoke 104 has a C shape in which an opening is partially formed, and a height of the opening is 55 cm as an example, and the entire weight of the iron yoke 104 is 14 tons as an example. The imaging space 102 is formed in the opening. A shape of the iron yoke 104 is set so that magnetic flux leaking to the outside is minimized. The opening has a pair of magnetic poles 203 which are processed into a recess surface in order to generate a uniform magnetic field. The doughnut-shaped vacuum containers 107 respectively accommodating the pair of high-temperature superconducting coils 105 are attached around the magnetic pole 203. If a current of 160 amperes flows through the high-temperature superconducting coils 105 from the magnet power source 106, a uniform magnetic field of, for example, 0.5 teslas is generated in the imaging space 102.

The coil bobbin 204 having a recess on an outer circumferential surface thereof, the radiation heat shield plate 206 disposed around the coil bobbin 204, and a superinsulator 208 covering an outer circumferential surface of the radiation heat shield plate 207 are disposed inside the vacuum container 107. A gap between the coil bobbin 204 and the vacuum container 107 constitutes a vacuum tank 207 with predetermined pressure, and forms a heat insulation structure.

A high-temperature superconducting wire (for example, a wire of MgB₂) as illustrated in FIG. 1 is wound in the recess of the coil bobbin 204 in a doughnut form so as to form the high-temperature superconducting coil 105. MgB₂ is a high-temperature superconducting material exhibiting a stable superconducting characteristic at 20 Kelvin (−253° C.) or lower. The coil bobbin 204 is made of aluminum having good heat conductivity.

A cavity for accommodating a nitrogen refrigerant 301 is formed in a circumferential direction inside the coil bobbin 204. In other words, a part of the coil bobbin 204 is also used as the refrigerant container 205. The cavity (refrigerant container 205) is preferably formed at a position which is more distant than the high-temperature superconducting coil 105 from the magnetic field center 201 in order to prevent a magnetic field of the imaging space 102 from being influenced. The cavity (refrigerant container 205) of the coil bobbin 204 is disposed over the high-temperature superconducting coil 105 in the vacuum container 107 which is disposed over the magnetic field center 201, and the cavity (refrigerant container 205) of the coil bobbin 204 is disposed under the high-temperature superconducting coil 105 in the vacuum container 107 which is disposed under the magnetic field center 201.

A penetration hole 205a which reaches the inside of the cavity is provided in a part of the coil bobbin 204 constituting the refrigerant container 205, and the refrigerant conduit 302 is provided therein. The refrigerant conduit 302 is drawn around the radiation heat shield plate 206 covering the coil bobbin 204 so that at least a partial interval thereof is in thermal contact with and along the radiation heat shield plate (that is, along at least one of an outer surface and an inner surface of the radiation heat shield plate 206), and then a tip end thereof is drawn out of the vacuum container 107 through the penetration hole formed in the vacuum container 107. The check valve 303 is provided at the tip end of the refrigerant conduit 302 so as to prevent external air from entering the refrigerant conduit 302. The refrigerant conduit 302 is used to introduce liquid nitrogen from the outside of the vacuum container 107 into the refrigerant container 205, and to discharge a nitrogen gas into which the liquid nitrogen in the refrigerant container 205 is vaporized, to the outside of the vacuum container 107. The refrigerant conduit 302 employs a tube made of a material which is thin and has low heat conductivity, for example, stainless steel, in order to prevent external heat from being transmitted to the coil bobbin 204.

The radiation heat shield plate 206 does not have a complete airtight structure but has slits or penetration holes to the extent of not influencing radiation heat blocking, and the refrigerant conduit 302 is drawn out of the radiation heat shield plate 206 through the slits or the like. In the superinsulator 208 (a part thereof is illustrated in FIG. 1), polyester sheets obtained by depositing aluminum and undergoing mirror surface treatment are wound in a several tens of layers, and thus radiation heat from the inner surface of the vacuum container 107 can be effectively blocked.

In order to fix the coil bobbin 204 to the vacuum container 107, a support column 209 is attached to the vacuum container 107 every quarter of the circumference of the high-temperature superconducting coil 105. Preferably, the support column 209 secures the rigidity resistant to an electromagnetic force and also has considerably low heat conductivity. Therefore, in the present embodiment, as the support column 209, a columnar rod with a diameter of 5 centimeters, made of fiber-reinforced plastic (FRP) is used. The radiation heat shield plate 206 is in thermal contact with the support column 209 in order to reduce a temperature gradient of the support column 209 near the coil bobbin 204.

As illustrated in FIG. 3, an opening penetrating through the iron yoke 104 is provided in a rear face portion of the superconducting magnet 103, and the freezer 108 is inserted thereinto. A cooling portion at the tip end of the freezer 108 is disposed inside a connection portion 210 which connects the upper and lower vacuum containers 107 to each other, and is in thermal contact with the coil bobbin 105 and the radiation heat shield plate 206. Specifically, for example, as the freezer 108, model CH-208R manufactured by Sumitomo Heavy Industries, Ltd. may be used. The freezer includes a 20-Kelvin cooling portion 211 and a 70-Kelvin cooling portion 212 which respectively have cooling capacities of 6 watts and 65 watts. A tip end 211a of the 20-Kelvin cooling portion 211 is connected to the upper and lower coil bobbins 204 via a copper mesh wire 213 and is thus in thermal contact therewith. A tip end 212a of the 70-Kelvin cooling portion 212 is connected to and in thermal contact with the radiation heat shield plate 206.

A current lead circuit and a temperature sensor circuit for applying a current to the high-temperature superconducting coil 105 are incorporated into the superconducting magnet 103. The pair of upper and lower high-temperature superconducting coils 105 are connected in series to each other inside the vacuum container 107, and are connected to a current lead wire (not illustrated in FIGS. 1 and 3) of the current lead circuit. The current lead wire is in thermal contact with the 70-Kelvin cooling portion 212, and is then guided to the outside of the vacuum container 107 so as to be connected to the magnet power source 106. Temperature sensors 214 of the temperature sensor circuit are embedded in a plurality of locations (only one location is illustrated in FIGS. 1 and 3) of the coil bobbin 204. The temperature sensor 214 is connected to a lead wire (not illustrated in FIGS. 1 and 3) made of phosphor bronze in order to minimize heat conduction, and the lead wire is guided to the outside of the vacuum container 107 so as to be connected to a sensor input terminal of the magnet power source 106, and thus transmits and receives a signal corresponding to the temperature of the high-temperature superconducting coil 105 detected by the temperature sensor 214 to and from the magnet power source 106.

With this structure, during normal operation of the freezer 108, the radiation heat shield plate 206 is cooled to about 70 Kelvin. As a result, the coil bobbin 204 and the high-temperature superconducting coil 105 are cooled to about 20 Kelvin even if radiation heat from the inner surface of the vacuum container 107 and conduction heat from the support column 209 and the lead circuit or the temperature sensor circuit are applied thereto.

<Regarding Phase Transition Between Solid Phase and Liquid Phase of Nitrogen>

A description will be made of the temperatures of the coil bobbin 204 and the high-temperature superconducting coil 105 in a state in which the freezer 108 is in a normal operation, and the high-temperature superconducting coil 105 and the radiation heat shield are stably cooled.

In the structure of the superconducting magnet 103 illustrated in FIGS. 1 and 3, a total of radiation heat transmitted to the radiation heat shield plate 206 from the inner surface of the vacuum container 107 through the superinsulator 208 of several tens of layers and conduction heat from the support column 209 is about 50 watts. Even if a loss caused by heat conduction from the current lead wire or the lead wire of the temperature sensor is taken into consideration, the radiation heat shield plate 206 is cooled to about 70 Kelvin because of the cooling capability of the freezer 108 corresponding to 70 Kelvin and 65 watts during normal operation.

The heat applied to the superconducting coil 105 is two types such as radiation heat of 70 Kelvin from the inner surface of the radiation heat shield plate 206 and conduction heat from the support column 209 and the current lead wire, and a sum of quantities of the heat is about 5 watts. The cooling capability of the freezer 108 at 20 Kelvin during normal operation is 6 watts, and the coil bobbin 204 is cooled to the temperature of 20 Kelvin.

Therefore, in a state in which the freezer 108 normally operates, the nitrogen refrigerant 301 of the refrigerant container 205 portion of the coil bobbin 204 is present as solid nitrogen and thus does not thermally change.

Next, a description will be made of the temperatures of the coil bobbin 204 and the superconducting coil 105 in a case where an operation of the freezer 108 is stopped and thus does not exhibit the cooling capability.

Since an amount of heat of a total of 50 watts including radiation heat from the inner surface of the vacuum container 107 and conduction heat from the support column 209 is applied to the radiation heat shield plate 206, the temperature of the radiation heat shield plate 206 increases in a predetermined rate due to operation stoppage of the freezer 108. In the superconducting coil 105, the radiation heat from the inner surface of the radiation heat shield plate 206 and the conduction heat from the support column 209 and the current lead wire exponentially increase over time from the operation stoppage of the freezer 108.

At this time, the solid nitrogen in the refrigerant container 205 of a part of the coil bobbin 204 works as a cold storage agent so as to suppress the temperature increase of the coil bobbin 204. For this reason, the temperatures of the coil bobbin 204 and the superconducting coil 105 are constant at 63 Kelvin (−210° C. which is a melting point of nitrogen) until phase transition that solid nitrogen changes to liquid nitrogen is completed.

Further, if an operation stoppage period of the freezer 108 is continued, the liquid nitrogen absorbs an amount of transferred heat is subject to phase transition to a nitrogen gas at 77 Kelvin (−196° C. which is a boiling point of nitrogen). The nitrogen gas is discharged to the outside of the vacuum container 107 through the incorporated refrigerant conduit 302 along the radiation heat shield plate 206. The nitrogen gas at 77 Kelvin exchanges heat with the radiation heat shield plate 206 while passing through the refrigerant conduit 302 so as to cool the radiation heat shield plate 206, and thus has a function of suppressing the temperature increase of the radiation heat shield plate 206.

Consequently, the temperatures of the high-temperature superconducting coil 105 and the radiation heat shield plate 206 are maintained at 77 Kelvin until the liquid nitrogen in the refrigerant container 205 completely transitions to the nitrogen gas. Therefore, since air (nitrogen and oxygen) in the vacuum tank 207 does not float as gases in the vacuum tank 207, and deterioration in a degree of vacuum is suppressed, it is also possible to maintain the heat insulation property of the vacuum tank 207 during operation stoppage of the freezer 108.

In addition, in a case where the operation stoppage of the freezer 108 is continued even after the whole of the liquid nitrogen in the refrigerant container 205 of the coil bobbin 204 transitions to the nitrogen gas, liquid nitrogen is successively replenished from the tip end of the refrigerant conduit 302 outside the vacuum container 107, and thus the temperatures of the high-temperature superconducting coil 105 and the radiation heat shield plate 206 can be maintained at 77 Kelvin.

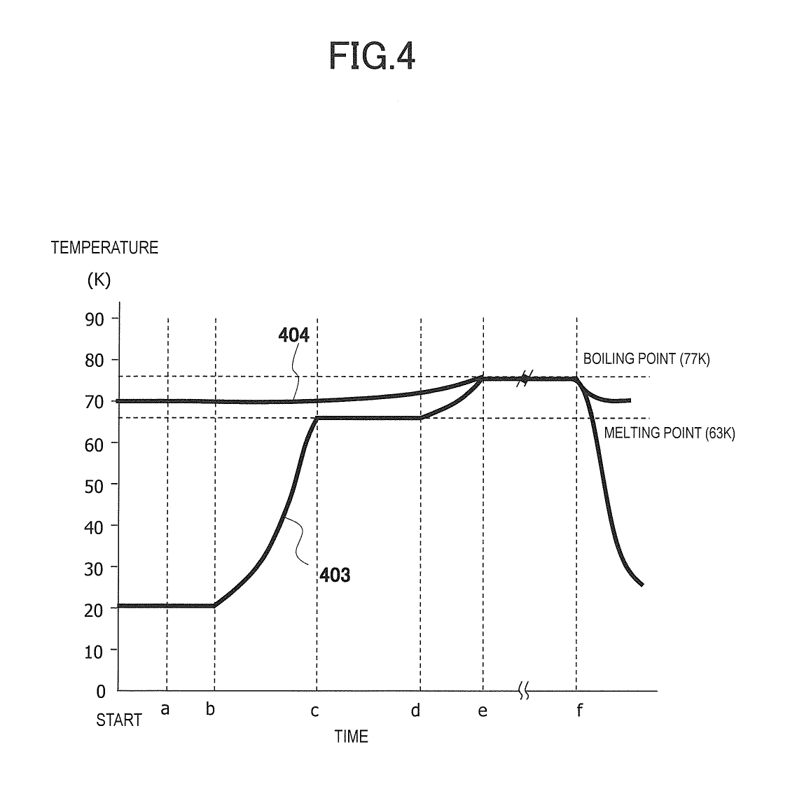

A detailed description will be made of changes in the temperatures of the high-temperature superconducting coil 105 and the radiation heat shield plate 206 with reference to a graph of FIG. 4. In the graph of FIG. 4, a transverse axis 401 expresses passage of time, and a longitudinal axis 402 expresses a temperature. In FIG. 4, graphs 403 and 404 respectively indicate the temperatures of the high-temperature superconducting coil 105 and the radiation heat shield plate 206.

A time point a on the time axis indicates a time point at which an operation of the freezer 108 is stopped. In a period from the start point on the time axis to the time point a at where the operation of the freezer 108 is stopped, stable cooling is performed by the freezer 108, and the temperature of the high-temperature superconducting coil 105 is maintained at 20 Kelvin, and the temperature of the radiation heat shield is maintained at 70 Kelvin. In a period in which the operation of the freezer 108 is being stopped from the time point a to a time point b, constant temperatures are maintained due to heat capacities of the constituent elements of the coil bobbin 204, the radiation heat shield plate 206, and the like, and the temperatures of the high-temperature superconducting coil 105 and the radiation heat shield plate 206 are respectively still maintained at 20 Kelvin and 70 Kelvin.

From the time point b, the temperature of the high-temperature superconducting coil 105 increases in a rate which is defined by a relationship among the coil bobbin 204, specific heat of the solid nitrogen refrigerant 301, and an amount of heat applied to the high-temperature superconducting coil 105. Consequently, the temperature of the high-temperature superconducting coil 105 increases to 63 Kelvin which is a melting point of the nitrogen refrigerant 301 in the refrigerant container 205. In a period from a time point c to a time point d, the solid nitrogen refrigerant 301 is subject to phase transition to liquid nitrogen, the whole amount of heat applied to the high-temperature superconducting coil 105 is an amount of melting heat of the nitrogen refrigerant 301, and thus the temperature of the high-temperature superconducting coil 105 does not change.

In a period from the time point d to a time point e, the temperature of the high-temperature superconducting coil 105 increases again in a rate which is defined by a relationship between specific heat of the liquid nitrogen refrigerant 301 and an amount of heat applied to the high-temperature superconducting coil 105, and the temperature of the high-temperature superconducting coil 105 increases to 77 Kelvin which is a boiling point of nitrogen.

In a period from the time point e to a time point f, the liquid nitrogen refrigerant 301 in the refrigerant container 205 of the coil bobbin 204 is discharged to the outside as a nitrogen gas through the refrigerant conduit 302. In this period, the whole of the amount of heat applied to the high-temperature superconducting coil 105 is consumed as vaporization heat of the liquid nitrogen, and thus the temperature of the high-temperature superconducting coil 105 exhibits a constant value of 77 Kelvin.

On the other hand, the temperature of the radiation heat shield plate 206 increases at a constant gradient which is defined by the heat capacity thereof and an amount of heat applied to the radiation heat shield plate 206 from the time point a to the time point e, and, from the time point e, the temperature increase is reduced due to cooling action caused by the nitrogen gas flowing through the refrigerant conduit 302.

At a time point f, the operation of the freezer 108 is resumed, and thus the radiation heat shield plate 206 and the high-temperature superconducting coil 105 are respectively cooled to 70 Kelvin and 20 Kelvin which are the equilibrium temperatures.

<Operation Flow of MRI Apparatus>

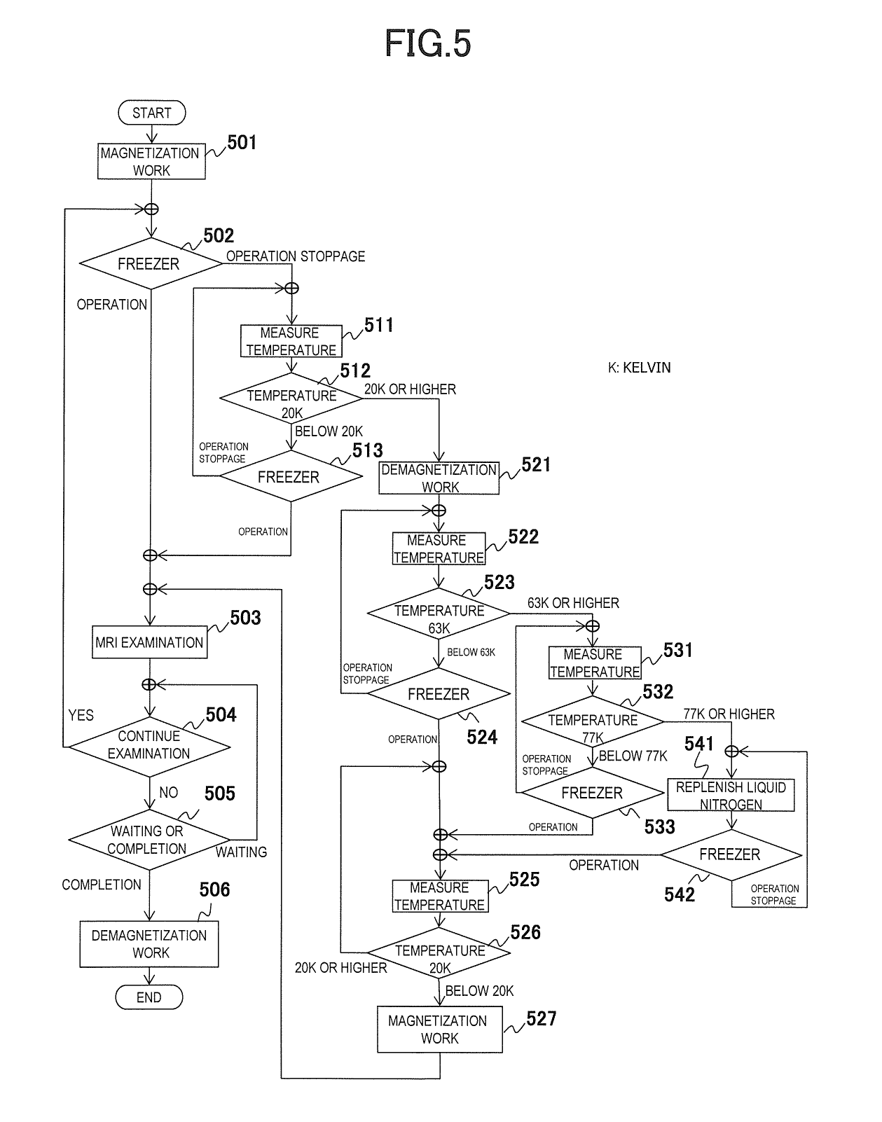

With reference to a flowchart of FIG. 5, a description will be made of an operation flow of the MRI apparatus in which the temperatures of the superconducting coil 105 and the radiation heat shield 206 change. The operation is performed by the computer 115 reading a program stored in a built memory and executing the program so as to control the magnet power source 106 and the like. The computer 115 also executes the program by using power supplied from a battery (not illustrated) during power failure.

The flows in FIG. 5 include a flow in a normal state, and a flow in which the normal state is rapidly returned through temperature management of the high-temperature superconducting coil 105 in a case where an operation of the freezer 108 is stopped. A summary of the flows will be described according to the following (1) to (5).

(1) In a flow from step S501 to step S506 on the left end of FIG. 5, the freezer 108 normally operates, the high-temperature superconducting coil 105 is cooled to 20 Kelvin which is equal to or lower than a threshold temperature, a stable magnetic field is generated in the imaging space 102, and imaging examination is performed. These steps correspond to the period from the start to the time point a in FIG. 4.

(2) In a case where an operation of the freezer 108 is stopped due to power failure or system failure, the flow shifts to a flow from step S511 to step S513. In the period during initial operation stoppage of the freezer 108, the high-temperature superconducting coil 105 is still cooled to and maintained at the threshold temperature of 20 Kelvin due to heat capacities of the constituent elements thereof, operation recovery of the freezer 108 is awaited, and the normal operation flow rapidly is returned. The period corresponds to the period from the time point a to the time point b in FIG. 4.

(3) If the operation of the freezer 108 is stopped for a long period of time, and the temperature of the high-temperature superconducting coil 105 starts to increase, the operation flow shifts to a right flow from step S521 to step S527. Consequently, a current flowing through the coil is made zero in order to prevent damage of the high-temperature superconducting coil 105, operation recovery of the freezer 108 is awaited, the cooling temperature of the high-temperature superconducting coil 105 is checked after the operation of the freezer 108 is recovered, a current is applied to the coil again, and the normal operation flow is returned. This corresponds to the period from the time point b to the time point c in FIG. 4.

(4) When the operation of the freezer is stopped for a long period of time, a flow from step S531 to step S533 occurs in a period in which the temperature of the high-temperature superconducting coil 105 reaches the nitrogen boiling point of 77 Kelvin from the melting point of solid nitrogen of 63 Kelvin. This corresponds to the time point c to the time point e in FIG. 4.

(5) A flow from step S541 to step S542 occurs in a case where the operation of the freezer 108 is stopped for a longer period of time. In this flow, liquid nitrogen as a refrigerant is vaporized so as to be discharged to the atmosphere, and operation recovery of the freezer 108 is awaited while replenishing liquid nitrogen. This corresponds to the period from the time point e to the time point f in FIG. 4.

Hereinafter, a description will be made of a specific operation of each unit in each step. Such an operation is performed under the control of the CPU 115.

Step S501: The magnet power source 106 makes a predefined current of 160 amperes flow through the superconducting coil 105 so as to generate a magnetic field before MRI examination is performed on that day. This operation may be performed according to an automatic starting function programmed into the computer 115, and may also be performed through an operator's operation on the input device 118.

Step S502: The freezer 108 cools the high-temperature superconducting coil 105 and the radiation heat shield plate 206 through consecutive operations. Consequently, the high-temperature superconducting coil 105 is cooled to 20 Kelvin, and the radiation heat shield plate 206 is cooled to 70 Kelvin. Here, the computer 115 determines whether the freezer 108 is normally operated, an operation thereof is stopped due to power failure or system failure. Regarding this determination, the computer 115 may determine whether or not the freezer 108 is normally operated by receiving an operation signal from the freezer, and may perform the determination by detecting a temperature on the basis of an output signal received from the temperature sensor disposed in the vacuum container 107 and by determining whether or not the temperature is within a predetermined temperature. In a case where the operation of the freezer 108 is normally performed, the flow proceeds to step S502. In a case where the operation of the freezer 108 is stopped, the flow proceeds to step S511.

Step S503: The computer 115 performs first imaging examination of the object 101.

Steps S504 and S505: The computer 115 determines whether or not the next examination of object 101 will be performed in step S504. In a case where examination will be performed, the flow returns to step S502, and the same steps as in the previous imaging examination of the object 101 are performed. In a case where there is no next examination of the object 101, the computer 115 proceeds to step S505 in which whether a completion step progresses or a state of waiting for unreserved objects such as an emergency patient occurs is determined on the basis of a predetermined determination criterion. The determination in step S505 may be performed, for example, according to a method of receiving the content that the operation judges that a day's examination is completed, and there is no next examination of an object through an operator's input operation on the input device 118, or a method of determining whether or not closing time of the medical institution has elapsed. In a case where waiting is determined in step S505, the flow returns to step S504. On the other hand, in a case where completion is determined, the flow proceeds to step S506.

Step S506: The supply of a current from the magnet power source 106 of the superconducting magnet 103 to the high-temperature superconducting coil 105 is stopped, and demagnetization work is performed. The demagnetization work may be performed through an automatic demagnetization operation in the computer 115, and may also be performed by the operator inputting a signal to the input device 118.

In a case where the operation of the freezer 108 is stopped in step S502, the flow proceeds to step S511.

Step S511: since the operation of the freezer 108 is stopped, the computer 115 receives an output signal from the temperature sensor in the vacuum container 107 so as to measure the temperature of the high-temperature superconducting coil 105. The output signal from the temperature sensor is received via the sequencer 117.

Step S512: It is determined whether or not the temperature of the high-temperature superconducting coil 105 exceeds the examination part of 20 Kelvin at which a stable superconducting state occurs. If the temperature is equal to or lower than 20 Kelvin, the flows proceeds to step S513 so as to enter a loop in which operation recovery of the freezer 108 is awaited, and the temperature measurement step S511 is returned. In a case where the temperature exceeds 20 Kelvin, the flow proceeds to step S521.

Step S521: If the temperature of the high-temperature superconducting coil 105 exceeds the threshold temperature of 20 Kelvin, the coil wire starts phase transition from the superconducting state, and thus electric resistance appears. Therefore, if the current of 160 amperes is continuously applied from the magnet power source 106, the coil is burnt out. For this reason, a current output from the magnet power source 106 is reduced so as to be made zero, thereby demagnetizing the superconducting coil 105.

Steps S522 to S524: The temperature of the demagnetized high-temperature superconducting coil 105 is measured, and operation recovery of the freezer is awaited if the temperature does not exceed 63 Kelvin. During this time, the nitrogen refrigerant 301 in the coil bobbin 204 absorbs entering heat as melting heat, so as to cool the high-temperature superconducting coil 105. If the whole nitrogen refrigerant 301 transitions to liquid nitrogen, and the temperature of the high-temperature superconducting coil 105 exceeds 63 Kelvin in step S523, the flow proceeds to step S531. If the operation of the freezer 108 is resumed before the temperature reaches 63 Kelvin, the flow proceeds to next step S525.

Steps S525 to S527: Since the operation of the freezer 108 is recovered, cooling of the high-temperature superconducting coil 105 and the radiation heat shield plate 206 are resumed. A waiting state occurs until the high-temperature superconducting coil 105 is cooled to the threshold temperature of 20 Kelvin, a current output from the magnet power source 106 is set to rated 160 amperes if cooled, so that the superconducting coil 105 is magnetized again, and the flow returns to step S503 in which MRI examination can be performed. Consequently, an operation of the MRI apparatus is returned to the normal flow.

On the other hand, if the temperature of the high-temperature superconducting coil 105 exceeds 63 Kelvin in step S523, the flow proceeds to step S531.

Steps S531 to S533: If a temperature is further continuously measured, and does not exceed a boiling point of the liquid nitrogen of 77 Kelvin, operation resumption of the freezer 108 is awaited. During this time, the nitrogen refrigerant 301 in the coil bobbin 204 absorbs entering heat as vaporization heat so as to cool the high-temperature superconducting coil 105. If the operation is resumed, the flow proceeds to the above step S525 in which the superconducting coil 105 is cooled to 20 Kelvin, and thus MRI examination can be performed.

On the other hand, in a case where it is determined that the temperature exceeds 77 Kelvin in step S532, the nitrogen refrigerant 301 is vaporized to be discharged to the atmosphere, and thus the flow proceeds to step S541.

Steps S541 and S542: The computer 115 displays, on the display 116, a display for prompting the operator to supply liquid nitrogen from the tip end of the refrigerant conduit 302 into the refrigerant container 205. Consequently, the operator successively replenishes liquid nitrogen from an external Dewar and waits for the operation of the freezer 108 to be resumed. If the operation of the freezer 108 is resumed, the flow proceeds to step S525 in which the superconducting coil 105 is cooled to 20 Kelvin and is then magnetized so that MRI examination can be performed.

As described above, the MRI apparatus of Embodiment 1 uses the superconducting coil 105 using the high-temperature superconducting wire, and can maintain the vacuum tank 207 at 77 Kelvin or lower for a long period of time even in a case where an operation of the freezer is stopped for a long period of time due to power failure or the like. Therefore, it is possible to provide an MRI apparatus which can prevent a heat insulation function from deteriorating due to deterioration in a degree of vacuum of the vacuum tank 207 so as to rapidly perform MRI examination, and thus has good practicability.

According to the present invention, since it is not necessary to use liquid helium which is expensive and is hard to transfer or keep, a superconducting MRI apparatus can be stably operated and can be provided for advanced clinical diagnosis even in an area deviated from a service network thereof or an area in which supply of power is unstable.

In Embodiment 1, a description has been made of the structure in which the refrigerant container 205 accommodating the nitrogen refrigerant 301 is built into the coil bobbin 204, but the coil bobbin 204 and the refrigerant container 205 may not necessarily be integrally formed with each other, and the coil bobbin 204 and the refrigerant container 205 may be provided separately from each other. Also in this case, preferably, the refrigerant container 205 is made of a material with good heat conductivity and is disposed to be in close contact with the coil bobbin 204.

### Embodiment 2

### Entire Configuration of MRI Apparatus of Embodiment 2

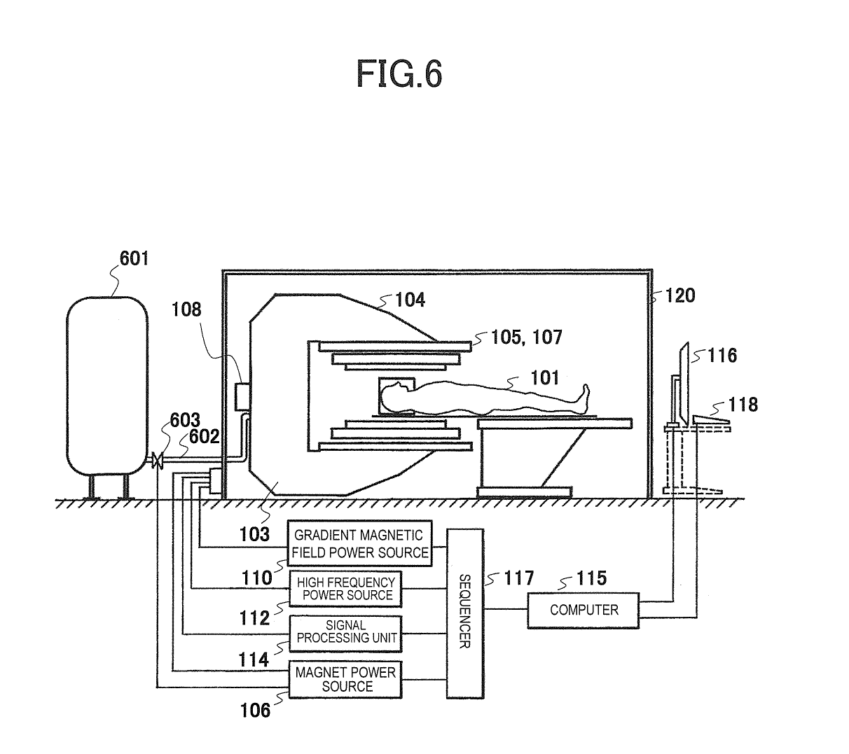

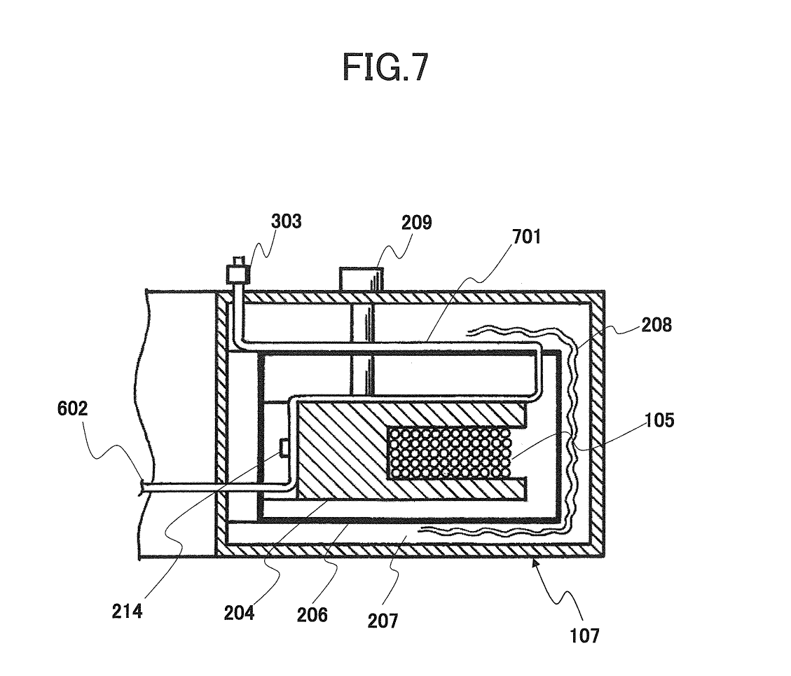

FIG. 6 illustrates a state in which an MRI apparatus of Embodiment 2 is provided in a medical institution and captures a medical diagnosis image of a patient who is an object. FIG. 7 is a sectional view of the vacuum container 107 of the superconducting magnet 103 of Embodiment 2.

A difference between the MRI apparatuses of Embodiment 2 and embodiment 1 is that a liquid nitrogen Dewar 601 is provided outside the examination room 120, and, the refrigerant container 205 is not formed in the coil bobbin 204, and a refrigerant conduit 701 connected to the liquid nitrogen Dewar 601 is disposed inside the vacuum container 107.

The refrigerant conduit 701, which is constituted of, for example, a copper pipe with favorable surface heat conduction, is disposed to be in close contact with the coil bobbin 204 and is then disposed to be in close contract with the radiation heat shield plate 206. In other words, the refrigerant conduit 701 is disposed to be in contact with the radiation heat shield plate on a downstream side of the coil bobbin 204 with respect to flow of a nitrogen refrigerant. Then, the refrigerant conduit 701 is drawn out of the vacuum container 107 and discharges a nitrogen gas (that is, vaporized refrigerant). The check valve 303 is attached to the tip end of the refrigerant conduit 701, and the check valve 303 prevents backflow of the air into the refrigerant conduit 701. The liquid nitrogen Dewar 601 is connected to the refrigerant conduit 701 via a heat insulation conduit 602. A switch valve 603 is disposed in the middle of the heat insulation conduit 602.

The switch valve 603 performs a switching operation in response to a control signal output from the magnet power source 106 under the control of the computer 115. For example, if an operation of the freezer 108 is stopped, and a value of the temperature sensor 214 attached to the coil bobbin 204 reaches, for example, 60 Kelvin, the computer 115 causes the magnetic control circuit incorporated into the magnet power source 106 to output a signal so as to open the switch valve 603. Consequently, liquid nitrogen is supplied to the refrigerant conduit 701 from the liquid nitrogen Dewar 601 via the heat insulation conduit 602.

The liquid nitrogen introduced into the refrigerant conduit 701 absorbs heat of the coil bobbin 204 at a portion of the refrigerant conduit 701 which is in close contact with the coil bobbin 204. Consequently, a part of the liquid nitrogen transitions to a nitrogen gas. The partially gaseous liquid nitrogen further flows through the refrigerant conduit 701, and absorbs heat of the radiation heat shield plate 206 at a portion of the refrigerant conduit 701 which is in close contact with the high-temperature radiation heat shield plate 206. Consequently, the liquid nitrogen undergoes phase transition to a nitrogen gas. The nitrogen gas further flows through the refrigerant conduit 701 and is discharged to the outside of the vacuum container 107.

As mentioned above, the high-temperature superconducting coil 105 and the radiation heat shield plate 206 are maintained at a temperature which is equal to or lower than 77 Kelvin corresponding to a boiling point of the liquid nitrogen due to heat exchange with the liquid nitrogen introduced from the Dewar 601. Consequently, the occurrence of degassing in which solid air is released in the vacuum tank 207, and thus vacuum heat insulation performance is maintained.

The MRI apparatus of Embodiment 2 can continuously perform an operation by automatically replenishing liquid nitrogen from the liquid nitrogen Dewar 601 even in a case where an operation of the freezer is stopped due to long-term power failure or system failure. A space for accommodating a refrigerant in the vacuum container 107 is not necessary, and thus it is possible to realize the compact vacuum container 107.

Other configurations of the MRI apparatus of Embodiment 2 are the same as those in Embodiment 1, and thus description thereof will not be repeated.

### REFERENCE SIGNS LIST

101 OBJECT, 102 IMAGING SPACE, 103 SUPERCONDUCTING MAGNET, 104 IRON YOKE, 105 HIGH-TEMPERATURE SUPERCONDUCTING COIL, 106 MAGNET POWER SOURCE, 107 VACUUM CONTAINER, 108 FREEZER, 109 GRADIENT MAGNETIC FIELD COIL ASSEMBLY, 110 GRADIENT MAGNETIC FIELD POWER SOURCE, 111 HIGH FREQUENCY TRANSMITTER COIL, 112 HIGH FREQUENCY POWER SOURCE, 114 SIGNAL PROCESSING UNIT, 115 COMPUTER, 117 SEQUENCER, 118 INPUT DEVICE, 203 MAGNETIC POLE, 204 COIL BOBBIN, 205 REFRIGERANT CONTAINER, 206 RADIATION HEAT SHIELD PLATE, 207 VACUUM TANK, 208 SUPERINSULATOR, 214 TEMPERATURE SENSOR, 301 NITROGEN REFRIGERANT, 302 REFRIGERANT CONDUIT, 303 CHECK VALVE, 601 LIQUID NITROGEN DEWAR, 602 HEAT INSULATION CONDUIT, 603 SWITCH VALVE, 701 REFRIGERANT CONDUIT

1. A magnetic resonance imaging apparatus comprising:
a superconducting coil that generates a static magnetic field;
a vacuum container that accommodates the superconducting coil therein;
a freezer that is in thermal contact with the superconducting coil so as to cool the superconducting coil; and
a refrigerant container that accommodates a refrigerant for cooling the superconducting coil in a case where a cooling function of the freezer is deteriorated or stopped,
wherein the refrigerant container is also used as a coil bobbin on which the superconducting coil is wound.

2. The magnetic resonance imaging apparatus according to claim 1,
wherein the refrigerant is a refrigerant which is solidified at a temperature to which the freezer cools the superconducting coil.

3. The magnetic resonance imaging apparatus according to claim 1,
wherein the refrigerant container is connected to a conduit through which the refrigerant flows, and
wherein an end portion of the conduit is drawn out of the vacuum container, and discharges the refrigerant which is gasified.

4. The magnetic resonance imaging apparatus according to claim 3,
wherein a check valve is provided at the end portion of the conduit.

5. The magnetic resonance imaging apparatus according to claim 3,
wherein a radiation heat shield plate is disposed to cover the superconducting coil in the vacuum container, and
wherein the conduit is disposed to be in contact with the radiation heat shield plate.

6. The magnetic resonance imaging apparatus according to claim 5,
wherein at least a partial interval of the conduit is disposed to be in thermal contact with and along the radiation heat shield plate.

7. The magnetic resonance imaging apparatus according to claim 1,
wherein the refrigerant container is disposed at a position which is more distant from the magnetic field center than the superconducting coil.

8. The magnetic resonance imaging apparatus according to claim 7,
wherein a pair of the vacuum containers are disposed to oppose each other with the magnetic field center interposed therebetween,
wherein the refrigerant container is disposed over the superconducting coil in the vacuum container disposed over the magnetic field center, and
wherein the refrigerant container is disposed under the superconducting coil in the vacuum container disposed under the magnetic field center.

9. A magnetic resonance imaging apparatus comprising:
a superconducting coil that generates a static magnetic field;
a vacuum container that accommodates the superconducting coil therein;
a freezer that is in thermal contact with the superconducting coil so as to cool the superconducting coil;
a coil bobbin that is disposed inside the vacuum container and on which the superconducting coil is wound, and a conduit that is disposed in contact with the coil bobbin; and
a refrigerant container that is disposed outside the vacuum container, and accommodates a refrigerant for cooling the superconducting coil
wherein the conduit is connected to the refrigerant container and through which the refrigerant flows.

10. The magnetic resonance imaging apparatus according to claim 9,
wherein an end portion of the conduit, which is drawn out of the vacuum container, is provided with a check valve, and discharges the refrigerant which is gasified.

11. The magnetic resonance imaging apparatus according to claim 9,
wherein a radiation heat shield plate is disposed to cover the superconducting coil in the vacuum container, and
wherein the conduit is disposed to be in contact with the radiation heat shield plate on a downstream side of the coil bobbin with respect to flow of the refrigerant.

12. The magnetic resonance imaging apparatus according to claim 1,
wherein the superconducting coil is a high-temperature superconducting coil.

13. The magnetic resonance imaging apparatus according to claim 1,
wherein the refrigerant is nitrogen.
